(19) United States
(12) Patent Application Publication
(10) Pub. No.: US 2024/0383490 A1
(43) Pub. Date: Nov. 21, 2024

(54) SYSTEMS AND METHODS FOR USING A PARTITIONED DEEP NEURAL NETWORK WITH A CONSTRAINED DATA CAP

(71) Applicant: STEERING SOLUTIONS IP HOLDING CORPORATION, Saginaw, MI (US)

(72) Inventor: Jonathan Hirscher, Manassas, VA (US)

(21) Appl. No.: 18/317,850

(22) Filed: May 15, 2023

(51) Int. Cl. B60W 50/02; H03M 7/30

(52) U.S. Cl. CPC B60W 50/0225; B60W 50/0205; H03M 7/702; B60W 2756/10

(57) ABSTRACT

A method using a partitioned deep neural network with a constrained data cap includes receiving, at a first machine learning model, raw data and generating compressed code using the raw data. The method also includes identifying values, of a plurality of values of the compressed code, that are outside of a value range, and generating, using the first machine learning model, a prediction value for each identified value, the prediction value for each respective value of the identified values predicting whether a respective value indicates an anomaly in the raw data. The method also includes further compressing, using the first machine learning model, portions of the compressed code associated with prediction values that are greater than a threshold. The method also includes communicating the portions of the compressed code to a second machine learning model, and receiving, from the second machine learning model, diagnostics information responsive to the portions of the compressed code.

### TECHNICAL FIELD

This disclosure relates to vehicle data processing and, in particular to systems and methods for using a partitioned deep neural network with a constrained data cap for vehicle data processing.

### BACKGROUND OF THE INVENTION

A vehicle, such as a car, truck, sport utility vehicle, crossover, mini-van, marine craft, aircraft, all-terrain vehicle, recreational vehicle, or other suitable forms of transportation, typically includes a steering system, such as an electronic power steering (EPS) system, a steer-by-wire (SbW) steering system, a hydraulic steering system, or other suitable steering system. The steering system of such a vehicle typically controls various aspects of vehicle steering including providing steering assist to an operator of the vehicle, controlling steerable wheels of the vehicle, and the like.

Such a steering system and/or other components of the vehicle may generate various data, which may be processed by one or more controllers of the vehicle. The data may be associated with any aspect of the vehicle and/or vehicle operation including, but not limited to, data indicating anomalies and/or faults in operations of the vehicle. Increasingly, the controllers of the vehicle may use one or more artificial intelligence networks, such as deep neural networks or other suitable networks, to process the vehicle data.

### SUMMARY OF THE INVENTION

This disclosure relates generally to partitioned neural networks.

An aspect of the disclosed embodiments includes a method using a partitioned deep neural network with a constrained data cap. The method includes receiving, at a first machine learning model, raw data and generating, using a first encoder of the first machine learning model, compressed code using the raw data. The method also includes identifying, using the first machine learning model, values, of a plurality of values of the compressed code, that are outside of a value range, and generating, using the first machine learning model, a prediction value for each identified value, the prediction value for each respective value of the identified values predicting whether a respective value indicates an anomaly in the raw data. The method also includes further compressing, using the first machine learning model, portions of the compressed code associated with prediction values that are greater than a threshold. The method also includes communicating the portions of the compressed code to a second machine learning model, and receiving, from the second machine learning model, diagnostics information responsive to the portions of the compressed code.

Another aspect of the disclosed embodiments includes a system using a partitioned deep neural network with a constrained data cap. The system includes a processor and a memory. The memory includes instructions that, when executed by the processor, case the processor to: receive, at a first machine learning model, raw data; generate, using a first encoder of the first machine learning model, compressed code using the raw data; identify, using the first machine learning model, values, of a plurality of values of the compressed code, that are outside of a value range; generate, using the first machine learning model, a prediction value for each identified value, the prediction value for each respective value of the identified values predicting whether a respective value indicates an anomaly in the raw data; further compress, using the first machine learning model, portions of the compressed code associated with prediction values that are greater than a threshold; communicate the portions of the compressed code to a second machine learning model; and receive, from the second machine learning model, diagnostics information responsive to the portions of the compressed code.

Another aspect of the disclosed embodiments includes an apparatus. The apparatus includes a processor and a memory. The memory includes instructions that, when executed by the processor, case the processor to: receive, at a first machine learning model, raw data; generate, using a first encoder of the first machine learning model, compressed code using the raw data; identify, using the first machine learning model, values, of a plurality of values of the compressed code, that are outside of a value range; generate, using the first machine learning model, a prediction value for each identified value, the prediction value for each respective value of the identified values predicting whether a respective value indicates an anomaly in the raw data; use vector quantization and entropy coding to further compress, using the first machine learning model, portions of the compressed code associated with prediction values that are greater than a threshold; communicate the portions of the compressed code to a second machine learning model; and receive, from the second machine learning model, diagnostics information responsive to the portions of the compressed code.

These and other aspects of the present disclosure are disclosed in the following detailed description of the embodiments, the appended claims, and the accompanying figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 generally illustrates a vehicle according to the principles of the present disclosure.

FIG. 2 generally illustrates a controller according to the principles of the present disclosure.

FIGS. 3-5 generally illustrate a partitioned neural network according to the principles of the present disclosure.

FIG. 6 is a flow diagram generally illustrating a method for using a partitioned neural network according to the principles of the present disclosure.

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described, a vehicle, such as a car, truck, sport utility vehicle, crossover, mini-van, marine craft, aircraft, all-terrain vehicle, recreational vehicle, or other suitable forms of transportation, typically includes a steering system, such as an electronic power steering (EPS) system, a steer-by-wire (SbW) steering system, a hydraulic steering system, or other suitable steering system. The steering system of such a vehicle typically controls various aspects of vehicle steering including providing steering assist to an operator of the vehicle, controlling steerable wheels of the vehicle, and the like.

Such a steering system and/or other components of the vehicle may generate various data, which may be processed by one or more controllers of the vehicle. The data may be associated with any aspect of the vehicle and/or vehicle operation including, but not limited to, data indicating anomalies and/or faults in operations of the vehicle. Increasingly, the controllers of the vehicle may use one or more artificial intelligence networks, such as deep neural networks or other suitable networks, to process the vehicle data.

Typically, deep neural networks (DNNs) can powerfully approximate highly nonlinear functions. However, even during an inference, such DNNs may be relatively resource intensive, and may use a relatively large amount of memory to store on a device. When deploying a DNN to an edge device the available compute and memory capacity is constrained, to the point that computation may have to be offloaded to another device (e.g. cloud compute), either to reduce the latency of the prediction or because the edge device is not capable of storing and executing the entire model.

Accordingly, systems and methods, such as those described herein, configured to use a partitioned deep neural network with a constrained data cap, may be desirable. In some embodiments, the systems and methods described herein may be configured to share the computational load between multiple devices. The systems and methods described herein may be configured to reduce an amount of data transferred between devices.

In some embodiments, the systems and methods described herein may be configured to reduce the amount of data transferred between devices using various data compression techniques (e.g., including, but not limited to lossless data compression techniques such as (i) entropy coding, such as Huffman coding or other suitable entropy coding techniques, (ii) compression by assigning smaller code lengths to symbols, which occur most frequently, given a set of discrete symbols, and/or (iii) vector quantitation). The systems and methods described herein may be configured to use lossy compression techniques, such as quantization, to convert continuous values to discrete values. Additionally, or alternatively, the systems and methods described herein may be configured to use vector quantization, which may map a continuous vector to the closest code vector in the codebook. Vector quantization has been used to compress DNNs and for representation learning in the domains of image, text, and audio.

In some embodiments, the systems and methods described herein may be configured to further compress data that has been vector quantized using entropy coding (e.g., because the codebook is a set of discrete values). The systems and methods described herein may be configured to partition or split a DNN between multiple devices to minimize prediction latency and energy consumption, anonymize data, reduce the size and compute power required for the DNN, and/or to reduce the amount of data transferred between the devices.

In some embodiments, the systems and methods described herein may be configured to use adaptive inference in the DNN to decrease both prediction latency and data transfer. The systems and methods described herein may be configured to, by progressively making predictions at differing model depths, make an early prediction before propagating through an entire model (e.g., if the early prediction is of high confidence). This may reduce the amount of compute resources used, and possibly prevent data transfer to another device.

In some embodiments, the systems and methods described herein may be configured to combine adaptive inference, partitioned neural networks, compression techniques, and/or other techniques, into a single neural network at training time (e.g., this may be particularly useful for domains with a continuous high-volume stream of data, which may balance the need for frequent high accuracy predictions and minimal data transfer).

In some embodiments, the systems and methods described herein may be configured to provide a neural network architecture, a training procedure, and an operating procedure. The systems and methods described herein may be configured to use two computing devices to, using the neural network architecture, the training procedure, and the operating procedure, reduce or minimize the amount of memory and compute used by a first computing device (e.g., such as a computing device associated with a vehicle or other suitable computing device), reduce or minimize the amount of data transferred between the first computing device and a second computing device (e.g., such as a cloud computing device or other suitable computing device), and increase or maximize the performance (e.g. accuracy) of the final prediction made on the second computing device.

In some embodiments, the first computing device may include a relatively less powerful computing device (e.g. an edge device or other suitable computing device), and the second computing device may include a relatively more powerful computing device (e.g. a cloud computing device or other suitable computing device).

In some embodiments, the systems and methods described herein may be configured to use a neural network, where many of the data compression techniques can be jointly optimized at the same or substantially the same time for increased or maximized compression. The systems and methods described herein may be configured to use two prediction heads in a single network to predict the same value at varying levels of performance (e.g. accuracy), to reduce the amount of data sent between devices, and combining this with a rule-based criterion, allowing for many observations to forgo an accurate prediction (e.g., as only a small subset of observations are sent to the second computing device). The systems and methods described herein may be configured to reduce latency, while making accurate predictions on every single observation.

In some embodiments, the systems and methods described herein may be configured to receive, at a first machine learning model, raw data. The first machine learning model is disposed within a vehicle. The raw data may correspond to vehicle data, such as steering system data of a steering system and/or any other suitable vehicle data. The systems and methods described herein may be configured to generate, using a first encoder of the first machine learning model, compressed code using the raw data. The systems and methods described herein may be configured to identify, using the first machine learning model, values, of a plurality of values of the compressed code, that are outside of a value range.

The systems and methods described herein may be configured to generate, using the first machine learning model, a prediction value for each identified value. The prediction value for each respective value of the identified values may predict whether a respective value indicates an anomaly in the raw data. The systems and methods described herein may be configured to further compress, using the first machine learning model, portions of the compressed code associated with prediction values that are greater than a threshold. Further compressing, using the first machine learning model, the portions of the compressed code associated with prediction values that are greater than the threshold may further include using vector quantization and/or entropy coding.

The systems and methods described herein may be configured to communicate the portions of the compressed code to a second machine learning model. The second machine learning model is disposed on a remote computing device. The remote computing device may associated with a cloud computing infrastructure or any other suitable remote computing device or infrastructure.

The systems and methods described herein may be configured to receive, from the second machine learning model, diagnostics information responsive to the portions of the compressed code. The diagnostics information may include classification information, severity information, monitoring parameter information, and/or any other suitable information. The systems and methods described herein may be configured to, in response to receiving the diagnostics information, initiate at least one corrective action procedure.

In some embodiments, the systems and methods described herein may be configured to, by training a network with two prediction heads (e.g., instead of two different networks), optimize the performance criteria. The systems and methods described herein may be configured to, when data is sent from the first device to the second device, output the pre-compressed code from a first encoder, which may be compatible with a second encoder without any further computation (e.g., preventing the need to send much large raw data to the second device). The systems and methods described herein may be configured to include vector quantization at training time to allow for the optimal selection of the codebook, for increased or maximized compression and performance.

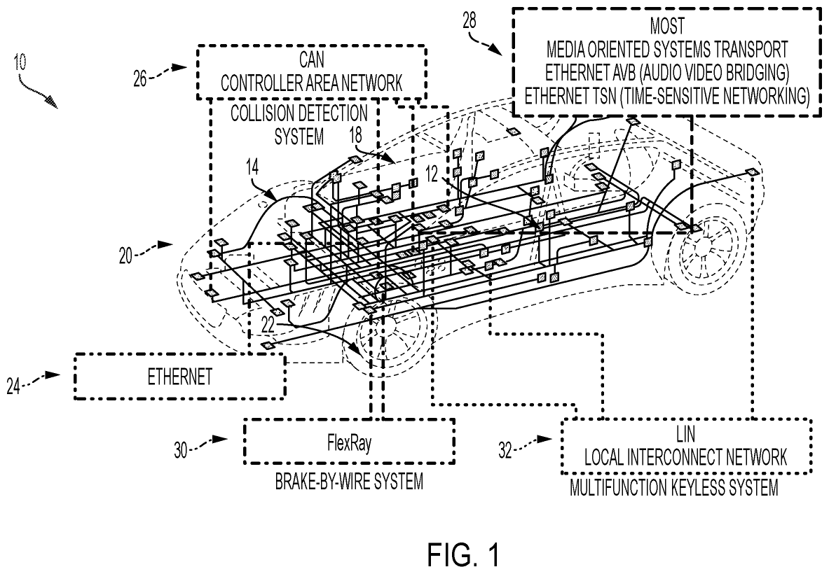

FIG. 1 generally illustrates a vehicle 10 according to the principles of the present disclosure. The vehicle 10 may include any suitable vehicle, such as a car, a truck, a sport utility vehicle, a mini-van, a crossover, any other passenger vehicle, any suitable commercial vehicle, or any other suitable vehicle. While the vehicle 10 is illustrated as a passenger vehicle having wheels and for use on roads, the principles of the present disclosure may apply to other vehicles, such as planes, boats, trains, drones, or other suitable vehicles

The vehicle 10 includes a vehicle body 12 and a hood 14. A passenger compartment 18 is at least partially defined by the vehicle body 12. Another portion of the vehicle body 12 defines an engine compartment 20. The hood 14 may be moveably attached to a portion of the vehicle body 12, such that the hood 14 provides access to the engine compartment 20 when the hood 14 is in a first or open position and the hood 14 covers the engine compartment 20 when the hood 14 is in a second or closed position. In some embodiments, the engine compartment 20 may be disposed on rearward portion of the vehicle 10 than is generally illustrated.

The passenger compartment 18 may be disposed rearward of the engine compartment 20, but may be disposed forward of the engine compartment 20 in embodiments where the engine compartment 20 is disposed on the rearward portion of the vehicle 10. The vehicle 10 may include any suitable propulsion system including an internal combustion engine, one or more electric motors (e.g., an electric vehicle), one or more fuel cells, a hybrid (e.g., a hybrid vehicle) propulsion system comprising a combination of an internal combustion engine, one or more electric motors, and/or any other suitable propulsion system.

In some embodiments, the vehicle 10 may include a petrol or gasoline fuel engine, such as a spark ignition engine. In some embodiments, the vehicle 10 may include a diesel fuel engine, such as a compression ignition engine. The engine compartment 20 houses and/or encloses at least some components of the propulsion system of the vehicle 10. Additionally, or alternatively, propulsion controls, such as an accelerator actuator (e.g., an accelerator pedal), a brake actuator (e.g., a brake pedal), a handwheel, and other such components are disposed in the passenger compartment 18 of the vehicle 10. The propulsion controls may be actuated or controlled by a operator of the vehicle 10 and may be directly connected to corresponding components of the propulsion system, such as a throttle, a brake, a vehicle axle, a vehicle transmission, and the like, respectively. In some embodiments, the propulsion controls may communicate signals to a vehicle computer (e.g., drive by wire) which in turn may control the corresponding propulsion component of the propulsion system. As such, in some embodiments, the vehicle 10 may be an autonomous vehicle.

In some embodiments, the vehicle 10 includes a transmission in communication with a crankshaft via a flywheel or clutch or fluid coupling. In some embodiments, the transmission includes a manual transmission. In some embodiments, the transmission includes an automatic transmission. The vehicle 10 may include one or more pistons, in the case of an internal combustion engine or a hybrid vehicle, which cooperatively operate with the crankshaft to generate force, which is translated through the transmission to one or more axles, which turns wheels 22. When the vehicle 10 includes one or more electric motors, a vehicle battery, and/or fuel cell provides energy to the electric motors to turn the wheels 22.

The vehicle 10 may include automatic vehicle propulsion systems, such as a cruise control, an adaptive cruise control, automatic braking control, other automatic vehicle propulsion systems, or a combination thereof. The vehicle 10 may be an autonomous or semi-autonomous vehicle, or other suitable type of vehicle. The vehicle 10 may include additional or fewer features than those generally illustrated and/or disclosed herein.

In some embodiments, the vehicle 10 may include an Ethernet component 24, a controller area network (CAN) bus 26, a media oriented systems transport component (MOST) 28, a FlexRay component 30 (e.g., brake-by-wire system, and the like), and a local interconnect network component (LIN) 32. The vehicle 10 may use the CAN bus 26, the MOST 28, the FlexRay Component 30, the LIN 32, other suitable networks or communication systems, or a combination thereof to communicate various information from, for example, sensors within or external to the vehicle, to, for example, various processors or controllers within or external to the vehicle. The vehicle 10 may include additional or fewer features than those generally illustrated and/or disclosed herein.

In some embodiments, the vehicle 10 may include a steering system, such as an EPS system, a steering-by-wire steering system (e.g., which may include or communicate with one or more controllers that control components of the steering system without the use of mechanical connection between the handwheel and wheels 22 of the vehicle 10), a hydraulic steering system (e.g., which may include a magnetic actuator incorporated into a valve assembly of the hydraulic steering system), or other suitable steering system.

The steering system may include an open-loop feedback control system or mechanism, a closed-loop feedback control system or mechanism, or combination thereof. The steering system may be configured to receive various inputs, including, but not limited to, a handwheel position, an input torque, one or more roadwheel positions, other suitable inputs or information, or a combination thereof.

Additionally, or alternatively, the inputs may include a handwheel torque, a handwheel angle, a motor velocity, a vehicle speed, an estimated motor torque command, other suitable input, or a combination thereof. The steering system may be configured to provide steering function and/or control to the vehicle 10. For example, the steering system may generate an assist torque based on the various inputs. The steering system may be configured to selectively control a motor of the steering system using the assist torque to provide steering assist to the operator of the vehicle 10.

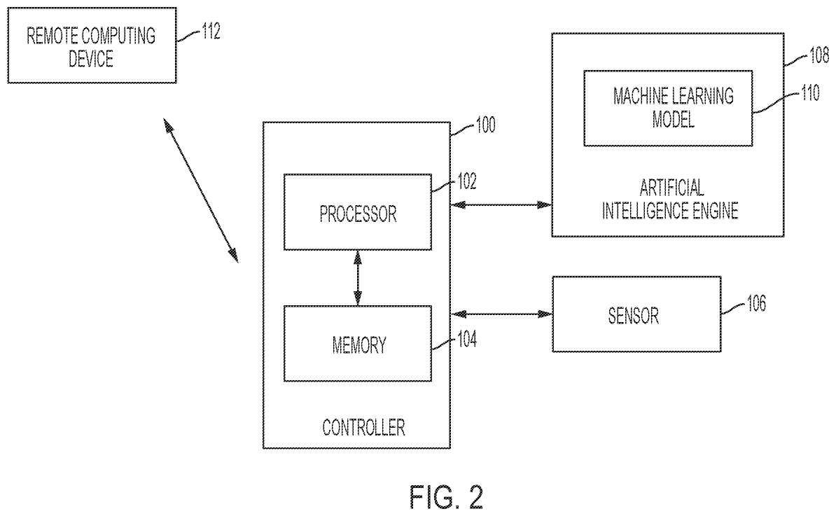

In some embodiments, the vehicle 10 may include a controller, such as controller 100, as is generally illustrated in FIG. 2. The controller 100 may include any suitable controller, such as an electronic control unit or other suitable controller. The controller 100 may be configured to control, for example, the various functions of the steering system and/or various functions of the vehicle 10. The controller 100 may include a processor 102 and a memory 104. The processor 102 may include any suitable processor, such as those described herein. Additionally, or alternatively, the controller 100 may include any suitable number of processors, in addition to or other than the processor 102. The memory 104 may comprise a single disk or a plurality of disks (e.g., hard drives), and includes a storage management module that manages one or more partitions within the memory 104. In some embodiments, memory 104 may include flash memory, semiconductor (solid state) memory or the like. The memory 104 may include Random Access Memory (RAM), a Read-Only Memory (ROM), or a combination thereof. The memory 104 may include instructions that, when executed by the processor 102, cause the processor 102 to, at least, control various aspects of the vehicle 10. Additionally, or alternatively, the memory 104 may include instructions that, when executed by the processor 102, cause the processor 102 to perform functions associated with the systems and methods described herein.

The controller 100 may receive one or more signals from various measurement devices or sensors 106 indicating sensed or measured characteristics of the vehicle 10. The sensors 106 may include any suitable sensors, measurement devices, and/or other suitable mechanisms. For example, the sensors 106 may include one or more torque sensors or devices, one or more handwheel position sensors or devices, one or more motor position sensor or devices, one or more position sensors or devices, other suitable sensors or devices, or a combination thereof. The one or more signals may indicate a handwheel torque, a handwheel angle, a motor velocity, a vehicle speed, other suitable information, or a combination thereof.

In some embodiments, the controller 100 may use or include one or more machine learning models 110. For example, an artificial intelligence engine 108 configured to use the machine learning model 110 to perform various aspects of the systems and methods described herein. The artificial intelligence engine 108 may include any suitable artificial intelligence engine and may be disposed on the vehicle 10. Additionally, or alternatively, another artificial intelligence engine (e.g., which may include feature similar to or different from the artificial intelligence engine 108) may be disposed on a remotely located computer, such as the remote computing device 112 (e.g., remote located from the vehicle 10). The remote computing device 112 may include any suitable remote computing device and may comprise at least a portion of a cloud computing device or infrastructure. The controller 100 may include a training engine capable of generating one or more machine learning models (e.g., such the machine learning model 110). Additionally, or alternatively, the machine learning model or models may be trained using any suitable training method and/or technique using any suitable computing device associated with or remote from the vehicle 10.

In some embodiments, the controller 100 may be configured to use the machine learning model 110 to process vehicle data (e.g., to detect anomalies in vehicle data or for any other suitable purpose) or for use in any suitable application in addition to or instead of the vehicle 10. Additionally, or alternatively, while the systems and methods described herein at least with respect to a vehicle and/or steering system, the systems and methods described herein may be configured to perform and/or be used in any suitable application, including and/or instead of the ones described herein.

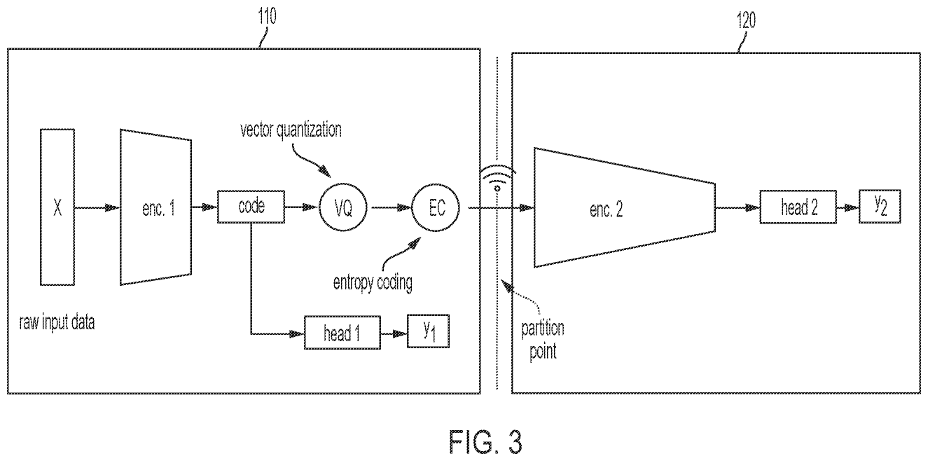

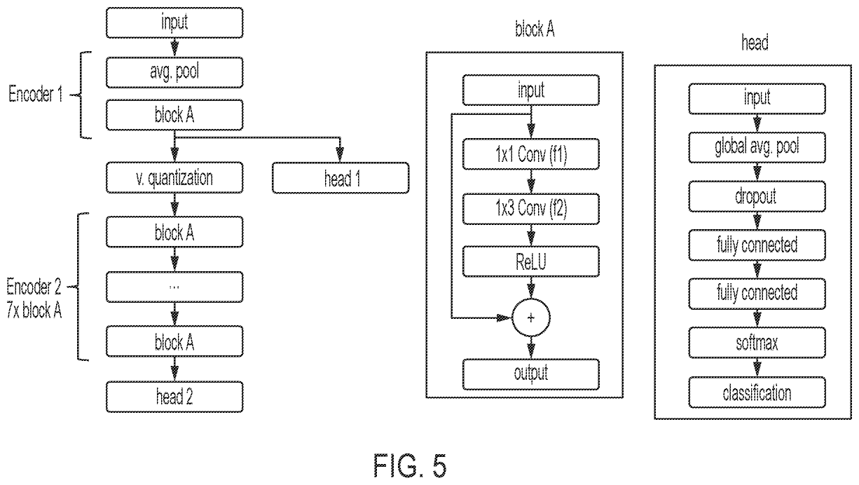

In some embodiments, the machine learning model 100 may comprise a neural network architecture (e.g., which may be referred to as a network herein), as is generally illustrated in FIGS. 3-5 (e.g., where FIG. 5 provides an example of the neural network). The neural network may include any suitable neural network configuration, in addition to or instead of those described and/or generally illustrated herein.

The network may include encoders (e.g., any combination of neural network layers, such as feed forward layers, convolutional layers, attention layers, recurrent layers, and/or the like), prediction heads, vector quantization (e.g., illustrated as VQ) blocks (e.g., for further compression), and/or entropy coding (e.g., illustrated as EC) blocks (e.g., for further compression). The network may be partitioned across two devices, such as the controller 100 and the remote computing device 112. For example, the machine learning model 110 may be used by or disposed on the controller 100, as described, and a machine learning model 120 may be used by or disposed on the remote commuting device 112. The controller 100 and the remote computing device 112 may communicate vehicle any suitable network or communications protocol. Additionally, or alternatively, it should be understood that, while the controller 100 and the remote computing device 112 are described herein, any suitable set of devices may be used to perform the systems and methods described herein.

The machine learning model 110 may include a first encoder (e.g., generally referred to herein as encoder 1 and illustrated as enc. 1) and a first head (e.g., generally referred to herein as head 1 and illustrated as head 1). The combination of the encoder 1 and the head 1 may use less space and compute resources than the combination of a second encoder (e.g., generally referred to herein as encoder 2 and illustrated as enc. 2) and a second head (e.g., generally referred to herein as head 2 and illustrated as head 2). Accordingly, the performance (e.g. accuracy) of the head 1 may be lower than that of head 2.

In some embodiments, the controller 100, the encoder 1 of the machine learning model 110, may compresses raw data X into compressed code. The controller 100, using head 1 of the machine learning model 110, may use a rule-based data selection criterion, based on a prediction output of head 1, to select when to send code to the remote computing device 112. The rule-based criterion may include only sending code to the remote computing device 112 when a confidence of the head 1 prediction is greater than a threshold or any other suitable criterion. This relatively low accuracy head 1 is thus used to filter through the continuous stream of raw data, and down select specific observations which have a higher probability of usefulness to the head 2 of the machine learning model 120.

The controller 100 may, using the vector quantization block of the machine learning model 110, compress code from a continuous vector space to a discrete space. The controller 100 may, using the entropy coding block of the machine learning model 110, further compress the code.

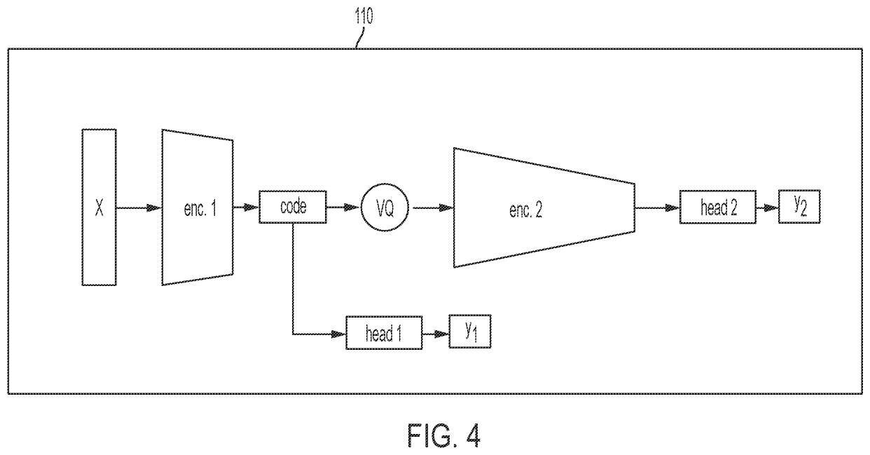

In some embodiments, when training the machine learning model 110, the entropy coding block may be removed, as is generally illustrated in FIG. 4. As such, the loss function for training is given as:

$$loss = {β}_{1} {L}_{1} + {β}_{2} {L}_{2} + {β}_{VQ} {L}_{VQ}$$

Where β₁, β₂, β_{VQ} are the tunable loss scaling hyperparameters for head 1, head 2, and VQ respectively, where L₁, L₂ are the loss functions selected for head 1 and head 2, respectively (e.g., cross entropy, mean squared error, and the like), and where L_{VQ} is the loss used to optimize the VQ codebook (e.g., the codebook alignment and commitment loss). The hyperparameters, as well as the many other used by the optimizer and neural network layers inside the heads, encoders, and VQ, and the tunable rule-based criterion attached to head 1, are tuned to until the following criteria are met: the memory and compute of encoder 1 and head 1 fit within the constraints of the controller 100; the data sent from the controller 100 to the remote computing device 112 is within the data transfer cap constraints; and the performance of head 2 is meets desired performance.

In some embodiments, the controller 100 may, for each observation (e.g. window of raw time series data of raw data X, which may include image data, sound data, sensor data, and/or the like.), provides the observation to the encoder 1, and head 1, which outputs a prediction. For example, head 1 classifies every observation for every time window (e.g., 8 seconds or other suitable tie window) on of the raw data X. If the classification of head 1 has a relatively high confidence, (e.g., satisfies the rule-based data selection criterion), the pre-compressed code is further compressed with the VQ and EC of the machine learning model 110. The controller 100 may communicate or send the compressed data to the remote computing device 112 as input to encoder 2. A final high performance prediction is made by head 2.

The remote computing device 112 may receive the compressed data. The remote computing device 112 may uncompress the compressed data and may provide the uncompressed data to the encoder 2 (e.g., which may be much larger and more powerful than the encoder 1), and a highly accurate prediction may be made by head 2.

In some embodiments, controller 100 receive, at the machine learning model 110, raw data X. The controller 100 may generate, using a encoder 1, compressed code using the raw data. The controller 100 may identify, using the head 1, values, of a plurality of values of the compressed code, that are outside of a value range. The value range may include any suitable range of values corresponding to any suitable criteria.

The controller 100 may generate, using the head 1, a prediction value for each identified value. The controller 100 may further compress, using the vector quantization block and/or the entropy coding block of the machine learning model 110, portions of the compressed code associated with prediction values that are greater than a threshold.

The controller 100 may communicate the portions of the compressed code to the machine learning model 120. The controller 100 may receive, from the machine learning model 120, diagnostics information responsive to the portions of the compressed code. The diagnostics information may include classification information, severity information, monitoring parameter information, and/or any other suitable information. The controller 100 may, in response to receiving the diagnostics information, initiate at least one corrective action procedure.

In some embodiments, the controller 100 may perform the methods described herein. However, the methods described herein as performed by the controller 100 are not meant to be limiting, and any type of software executed on a controller or processor can perform the methods described herein without departing from the scope of this disclosure. For example, a controller, such as a processor executing software within a computing device, can perform the methods described herein.

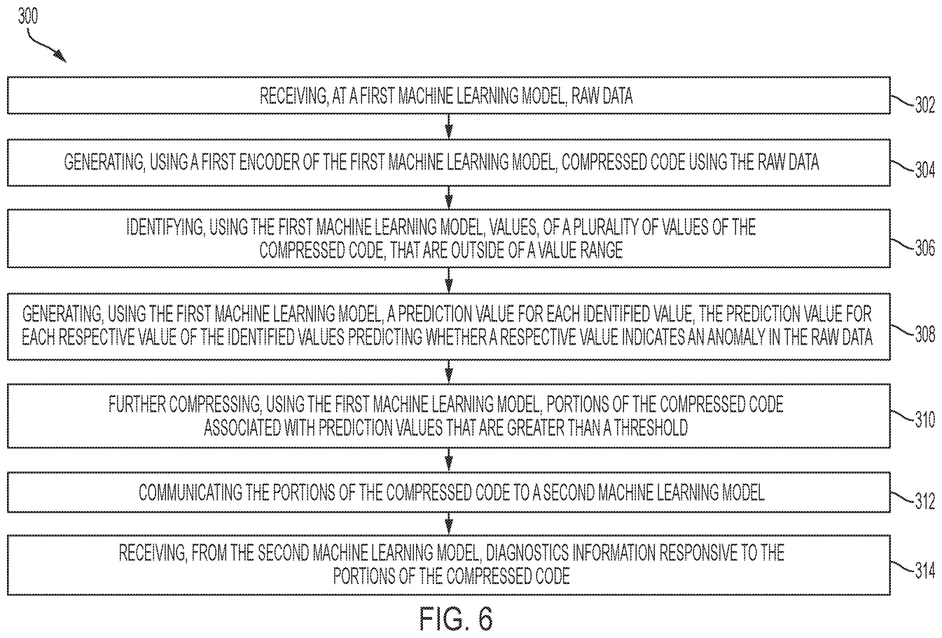

FIG. 6 is a flow diagram generally illustrating method 300 for using a partitioned neural network according to the principles of the present disclosure. At 302, the method 300 receives, at a first machine learning model, raw data.

At 304, the method 300 generates, using a first encoder of the first machine learning model, compressed code using the raw data.

At 306, the method 300 identifies, using the first machine learning model, values, of a plurality of values of the compressed code, that are outside of a value range.

At 308, the method 300 generates, using the first machine learning model, a prediction value for each identified value. The prediction value for each respective value of the identified values may predict whether a respective value indicates an anomaly in the raw data.

At 310, the method 300 further compresses, using the first machine learning model, portions of the compressed code associated with prediction values that are greater than a threshold.

At 312, the method 30 communicates the portions of the compressed code to a second machine learning model.

At 314, the method 300 receives, from the second machine learning model, diagnostics information responsive to the portions of the compressed code.

In some embodiments, a method using a partitioned deep neural network with a constrained data cap includes receiving, at a first machine learning model, raw data and generating, using a first encoder of the first machine learning model, compressed code using the raw data. The method also includes identifying, using the first machine learning model, values, of a plurality of values of the compressed code, that are outside of a value range, and generating, using the first machine learning model, a prediction value for each identified value, the prediction value for each respective value of the identified values predicting whether a respective value indicates an anomaly in the raw data. The method also includes further compressing, using the first machine learning model, portions of the compressed code associated with prediction values that are greater than a threshold. The method also includes communicating the portions of the compressed code to a second machine learning model, and receiving, from the second machine learning model, diagnostics information responsive to the portions of the compressed code.

In some embodiments, the method also includes, in response to receiving the diagnostics information, initiating at least one corrective action procedure. In some embodiments, the diagnostics information includes at least one of issue classification information, severity information, and monitoring parameter information. In some embodiments, the first machine learning model is disposed within a vehicle. In some embodiments, the second machine learning model is disposed on a remote computing device. In some embodiments, the remote computing device is associated with a cloud computing infrastructure. In some embodiments, the raw data corresponds to a steering system of a vehicle. In some embodiments, the steering system includes an electronic power steering system. In some embodiments, further compressing, using the first machine learning model, the portions of the compressed code associated with prediction values that are greater than the threshold further includes using vector quantization. In some embodiments, further compressing, using the first machine learning model, the portions of the compressed code associated with prediction values that are greater than the threshold further includes using entropy coding.

In some embodiments, a system using a partitioned deep neural network with a constrained data cap includes a processor and a memory. The memory includes instructions that, when executed by the processor, case the processor to: receive, at a first machine learning model, raw data; generate, using a first encoder of the first machine learning model, compressed code using the raw data; identify, using the first machine learning model, values, of a plurality of values of the compressed code, that are outside of a value range; generate, using the first machine learning model, a prediction value for each identified value, the prediction value for each respective value of the identified values predicting whether a respective value indicates an anomaly in the raw data; further compress, using the first machine learning model, portions of the compressed code associated with prediction values that are greater than a threshold; communicate the portions of the compressed code to a second machine learning model; and receive, from the second machine learning model, diagnostics information responsive to the portions of the compressed code.

In some embodiments, the instructions further cause the processor to, in response to receiving the diagnostics information, initiating at least one corrective action procedure. In some embodiments, the diagnostics information includes at least one of issue classification information, severity information, and monitoring parameter information. In some embodiments, the first machine learning model is disposed within a vehicle. In some embodiments, the second machine learning model is disposed on a remote computing device. In some embodiments, the remote computing device is associated with a cloud computing infrastructure. In some embodiments, the raw data corresponds to a steering system of a vehicle. In some embodiments, the instructions further cause the processor to further compress, using the first machine learning model, the portions of the compressed code associated with prediction values that are greater than the threshold further using vector quantization. In some embodiments, the instructions further cause the processor to further compress, using the first machine learning model, the portions of the compressed code associated with prediction values that are greater than the threshold further using entropy coding.

In some embodiments, an apparatus includes a processor and a memory. The memory includes instructions that, when executed by the processor, case the processor to: receive, at a first machine learning model, raw data; generate, using a first encoder of the first machine learning model, compressed code using the raw data; identify, using the first machine learning model, values, of a plurality of values of the compressed code, that are outside of a value range; generate, using the first machine learning model, a prediction value for each identified value, the prediction value for each respective value of the identified values predicting whether a respective value indicates an anomaly in the raw data; use vector quantization and entropy coding to further compress, using the first machine learning model, portions of the compressed code associated with prediction values that are greater than a threshold; communicate the portions of the compressed code to a second machine learning model; and receive, from the second machine learning model, diagnostics information responsive to the portions of the compressed code.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

The word “example” is used herein to mean serving as an example, instance, or illustration. Any aspect or design described herein as “example” is not necessarily to be construed as preferred or advantageous over other aspects or designs. Rather, use of the word “example” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” throughout is not intended to mean the same embodiment or implementation unless described as such.

Implementations the systems, algorithms, methods, instructions, etc., described herein can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably.

As used herein, the term module can include a packaged functional hardware unit designed for use with other components, a set of instructions executable by a controller (e.g., a processor executing software or firmware), processing circuitry configured to perform a particular function, and a self-contained hardware or software component that interfaces with a larger system. For example, a module can include an application specific integrated circuit (ASIC), a Field Programmable Gate Array (FPGA), a circuit, digital logic circuit, an analog circuit, a combination of discrete circuits, gates, and other types of hardware or combination thereof. In other embodiments, a module can include memory that stores instructions executable by a controller to implement a feature of the module.

Further, in one aspect, for example, systems described herein can be implemented using a general-purpose computer or general-purpose processor with a computer program that, when executed, carries out any of the respective methods, algorithms, and/or instructions described herein. In addition, or alternatively, for example, a special purpose computer/processor can be utilized which can contain other hardware for carrying out any of the methods, algorithms, or instructions described herein.

Further, all or a portion of implementations of the present disclosure can take the form of a computer program product accessible from, for example, a computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or a semiconductor device. Other suitable mediums are also available.

The above-described embodiments, implementations, and aspects have been described in order to allow easy understanding of the present invention and do not limit the present invention. On the contrary, the invention is intended to cover various modifications and equivalent arrangements included within the scope of the appended claims, which scope is to be accorded the broadest interpretation so as to encompass all such modifications and equivalent structure as is permitted under the law.

What is claimed is:

1. A method using a partitioned deep neural network with a constrained data cap, the method comprising:
receiving, at a first machine learning model, raw data;
generating, using a first encoder of the first machine learning model, compressed code using the raw data;
identifying, using the first machine learning model, values, of a plurality of values of the compressed code, that are outside of a value range;
generating, using the first machine learning model, a prediction value for each identified value, the prediction value for each respective value of the identified values predicting whether a respective value indicates an anomaly in the raw data;
further compressing, using the first machine learning model, portions of the compressed code associated with prediction values that are greater than a threshold;
communicating the portions of the compressed code to a second machine learning model; and
receiving, from the second machine learning model, diagnostics information responsive to the portions of the compressed code.

2. The method of claim 1, further comprising, in response to receiving the diagnostics information, initiating at least one corrective action procedure.

3. The method of claim 1, wherein the diagnostics information includes at least one of issue classification information, severity information, and monitoring parameter information.

4. The method of claim 1, wherein the first machine learning model is disposed within a vehicle.

5. The method of claim 1, wherein the second machine learning model is disposed on a remote computing device.

6. The method of claim 5, wherein the remote computing device is associated with a cloud computing infrastructure.

7. The method of claim 1, wherein the raw data corresponds to a steering system of a vehicle.

8. The method of claim 7, wherein the steering system includes an electronic power steering system.

9. The method of claim 1, wherein further compressing, using the first machine learning model, the portions of the compressed code associated with prediction values that are greater than the threshold further includes using vector quantization.

10. The method of claim 1, wherein further compressing, using the first machine learning model, the portions of the compressed code associated with prediction values that are greater than the threshold further includes using entropy coding.

11. A system for using a partitioned deep neural network with a constrained data cap, the system comprising:
a processor; and
a memory including instructions that, when executed by the processor, case the processor to:
receive, at a first machine learning model, raw data;
generate, using a first encoder of the first machine learning model, compressed code using the raw data;
identify, using the first machine learning model, values, of a plurality of values of the compressed code, that are outside of a value range;
generate, using the first machine learning model, a prediction value for each identified value, the prediction value for each respective value of the identified values predicting whether a respective value indicates an anomaly in the raw data;
further compress, using the first machine learning model, portions of the compressed code associated with prediction values that are greater than a threshold;
communicate the portions of the compressed code to a second machine learning model; and
receive, from the second machine learning model, diagnostics information responsive to the portions of the compressed code.

12. The system of claim 11, wherein the instructions further cause the processor to, in response to receiving the diagnostics information, initiating at least one corrective action procedure.

13. The system of claim 11, wherein the diagnostics information includes at least one of issue classification information, severity information, and monitoring parameter information.

14. The system of claim 11, wherein the first machine learning model is disposed within a vehicle.

15. The system of claim 11, wherein the second machine learning model is disposed on a remote computing device.

16. The system of claim 15, wherein the remote computing device is associated with a cloud computing infrastructure.

17. The system of claim 11, wherein the raw data corresponds to a steering system of a vehicle.

18. The system of claim 11, wherein the instructions further cause the processor to further compress, using the first machine learning model, the portions of the compressed code associated with prediction values that are greater than the threshold further using vector quantization.

19. The system of claim 11, wherein the instructions further cause the processor to further compress, using the first machine learning model, the portions of the compressed code associated with prediction values that are greater than the threshold further using entropy coding.

20. An apparatus comprising:
a processor; and
a memory including instructions that, when executed by the processor, case the processor to:
receive, at a first machine learning model, raw data;
generate, using a first encoder of the first machine learning model, compressed code using the raw data;
identify, using the first machine learning model, values, of a plurality of values of the compressed code, that are outside of a value range;
generate, using the first machine learning model, a prediction value for each identified value, the prediction value for each respective value of the identified values predicting whether a respective value indicates an anomaly in the raw data;
use vector quantization and entropy coding to further compress, using the first machine learning model, portions of the compressed code associated with prediction values that are greater than a threshold;
communicate the portions of the compressed code to a second machine learning model; and
receive, from the second machine learning model, diagnostics information responsive to the portions of the compressed code.
